(19) United States
(12) Patent Application Publication
(10) Pub. No.: US 2018/0231689 A1
(43) Pub. Date: Aug. 16, 2018

(54) Item Having Optimized Adhesive Properties and Comprising a Silicon Organic Layer

(71) Applicant: ESSILOR INTERNATIONAL, Charenton-le-Pont (FR)

(72) Inventor: Sébastien CHIAROTTO, Charenton-le-Pont (FR)

(21) Appl. No.: 15/750,040

(22) PCT Filed: Aug. 5, 2016
(86) PCT No.: PCT/FR2016/052041

§ 371 Date: Feb. 2, 2018

(30) Foreign Application Priority Data
Aug. 5, 2015 (FR) 1557558

(51) Int. Cl. G02B 1/111; C23C 14/30; C23C 14/12; C23C 14/08; C23C 14/10; C23C 16/40

(52) U.S. Cl. CPC G02B 1/111; C23C 14/30; C23C 14/12; C23C 16/50; C23C 14/10; C23C 16/401; C23C 16/405; C23C 14/083

(57) ABSTRACT

An item including a substrate having at least one main surface coated with an interference coating including: a layer A with refractive index less than or equal to 1.65 and obtained via vacuum deposition assisted by an ion source made of at least one organosilicon compound A and making direct contact with layer A, layer B having a refractive index greater than 1.65 and is obtained via vacuum deposition assisted by an ion source made of at least one metal oxide and at least one organosilicon compound B, layer B containing at least one metal oxide having a refractive index greater than or equal to 1.8, or a layer C that includes a silicon oxide, has a thickness less than or equal to 15 nm, and makes direct contact with a layer E that includes at least one metal oxide having a refractive index greater than or equal to 1.8.

The present invention generally relates to an article, preferably an optical article, especially an ophthalmic lens, possessing an interference coating including at least one layer of organosilicon nature, preferably an antireflection coating, the adherence properties of which have been improved, and to a process for producing such an article.

It is known to treat ophthalmic glasses, whether they are mineral or organic, so as to prevent the formation of parasitic reflections which are a nuisance to the wearer of the lens and the people they are interacting with. The lens is then provided with a mono- or multilayer antireflection coating, generally made of mineral material, which exhibits, in the second case, an alternation of layers of high refractive index and of low refractive index.

A reflective coating produces the reverse effect, that is to say that it increases the reflection of the light rays. Such a type of coating is used, for example, to obtain a mirror effect in sunglass lenses.

During the trimming and fitting of an eyeglass at an optician's practice, the eyeglass undergoes mechanical deformations which can produce cracks in the mineral reflective or antireflection interference coatings, in particular when the operation is not carried out with care. Similarly, thermal stresses (heating of the frame) can produce cracks in the interference coating. Depending on the number and the size of the cracks, the latter can interfere with the field of view of the wearer and prevent the eyeglass from being sold. Furthermore, while the treated organic eyeglasses are being worn, scratches can appear.

In mineral interference coatings, some scratches lead to cracking, making the scratches more visible because of scattering of light.

The application EP 1 324 078 describes a lens coated with a multilayer antireflection coating comprising an alternation of layers of high and of low refractive index, the external layer of which is a layer of low refractive index (1.42-1.48) consisting of a hybrid layer, obtained by ion-assisted vacuum co-evaporation of an organic compound (for example, polyethylene glycol glycidyl ether, polyethylene glycol monoacrylate or N-(3-trimethoxysilylpropyl)gluconamide) and of at least one inorganic compound (silica or silica and alumina) simultaneously.

The patents U.S. Pat. No. 6,919,134 and U.S. Pat. No. 7,318,959 describe an optical article comprising an antireflection coating comprising at least one layer known as “hybrid” obtained by co-evaporation of an organic compound, which may be an organosilicon compound such as a modified silicone oil, and an inorganic compound (SiO₂, SiO₂+Al₂O₃, Nb₂O₅, Ta₂O₅, TiO₂, ZrO₂ or Y₂O₃), which confers on it a better adhesion, a better thermal resistance and a better abrasion resistance. The amount of organic compound in the hybrid layer generally varies from 0.02% to 70% by weight and preferably from 0.5% to 25%. The hybrid layer is generally deposited by co-evaporation under ion assistance.

The application WO 2013/098531, in the name of the applicant, describes an article having improved thermomechanical performances, comprising a substrate having at least one main surface coated with a multilayer interference coating, said coating comprising a layer A not formed from inorganic precursor compounds having a refractive index of less than or equal to 1.55, which constitutes:

either the external layer of the interference coating,

or an intermediate layer making direct contact with the external layer of the interference coating, this external layer of the interference coating being in this second case an additional layer having a refractive index smaller than or equal to 1.55,

said layer A having been obtained by deposition, under ion beam, of activated species issued from at least one precursor compound in gaseous form of organosilicon nature such as octamethylcyclotetrasiloxane (OMCTS).

Patent application WO 2014/199103, in the name of the applicant, describes a multilayer interference coating obtained in a similar technology, the external layer of which is a layer A obtained by deposition, under ion beam, of activated species issued from at least one precursor compound in gaseous form of organosilicon nature such as 2,4,6,8-tetramethylcyclotetrasiloxane (TMCTS).

The two latter patent applications show that it is possible to make a layer formed by ion-assisted vacuum deposition of an organosilicon compound adhere to an inorganic layer of high refractive index.

In contrast, depositing these two layers in inverse order is problematic. Specifically, the inventors have observed that it is difficult to obtain the adhesion of a high-refractive-index inorganic layer when it is deposited directly on a low-refractive-index layer formed by ion-assisted vacuum deposition of an organosilicon compound. The experimental section gives the example of an adhesion defect observed at the interface of a ZrO₂ layer deposited directly on a low-refractive-index layer based on organosilicon compound, leading to substantial cracking over all the area of the eyeglass.

One objective of the invention is to obtain an interference coating, in particular an antireflection coating, allowing one or more layers based on organosilicon compounds to be integrated into the interior of an interference coating with a view to obtaining improved thermomechanical properties, while preserving a good optical performance, in particular a high refractive index, and while solving the aforementioned problem of adherence.

The invention is targeted in particular at articles possessing an improved critical temperature, that is to say exhibiting a good resistance to cracking when they are subjected to an increase in temperature and/or a good resistance to cracking when they are subjected to deformation and/or a good resistance to abrasion. Another objective of the invention is to provide a process for manufacturing an article equipped with an interference coating that is simple, easy to carry out and reproducible.

The inventors have developed two means for solving the problem to be addressed while meeting the set objectives, one being based on a modification of the nature of the material of the high-refractive-index layer, which layer is replaced by a layer obtained by deposition, under assistance from a source of ions, of activated species obtained from a precursor material of organic nature and from a precursor material of inorganic nature, the other being based on the insertion of a layer allowing the adhesion between the high-refractive-index layer and the low-refractive-index layer based on organosilicon compounds.

Thus, the targeted aims are therefore achieved according to the invention with an article comprising a substrate having at least one main surface coated with an interference coating comprising, in order starting from the substrate:

a layer A obtained by vacuum deposition, assisted by a source of ions, of at least one organosilicon compound A, said layer A having a refractive index lower than or equal to 1.65, and, making direct contact with this layer A,

either a layer B obtained by vacuum deposition, assisted by a source of ions, of at least one metal oxide and at least one organosilicon compound B, said layer B having a refractive index higher than 1.65 and containing at least one metal oxide having a refractive index higher than or equal to 1.8,

or a layer C comprising a silicon oxide and having a thickness lower than or equal to 15 nm, making direct contact with a layer E comprising at least one metal oxide having a refractive index higher than or equal to 1.8.

In the present patent application, when an article comprises one or more coatings at its surface, the expression “to deposit a layer or a coating on the article” means that a layer or a coating is deposited on the uncovered (exposed) surface of the external coating of the article, that is to say its coating furthest from the substrate.

A coating which is “on” a substrate or which has been deposited “on” a substrate is defined as a coating which (i) is positioned above the substrate, (ii) is not necessarily in contact with the substrate (although it preferably is in contact), that is to say one or more intermediate coatings can be positioned between the substrate and the coating in question, and (iii) does not necessarily completely cover the substrate (although it preferably covers it). When “a layer 1 is located under a layer 2”, it will be understood that the layer 2 is further from the substrate than the layer 1.

The article produced according to the invention comprises a substrate, preferably a transparent substrate, having front and back main faces, at least one of said main faces and preferably both main faces comprising an interference coating comprising at least one layer A. A layer A is defined as being a layer obtained by vacuum deposition, assisted by a source of ions, of at least one organosilicon compound A, said layer A having a refractive index lower than or equal to 1.65.

The “back face” of the substrate (the back face generally being concave) is understood to mean the face which, when the article is being used, is closest to the eye of the wearer. Conversely, the “front face” of the substrate (the front face generally being convex) is understood to mean the face which, when the article is being used, is furthest from the eye of the wearer.

Although the article according to the invention can be any article, such as a screen, a glazing unit, a pair of protective glasses which can be used in particular in a working environment, a mirror or an article used in electronics, it preferably constitutes an optical article, in particular an optical filter, better still an optical lens and even better still an ophthalmic lens, for a pair of spectacles, or an optical or ophthalmic lens blank, such as a semi-finished optical lens, in particular a spectacle eyeglass. The lens can be a polarized or tinted lens or a photochromic or electrochromic lens.

The interference coating according to the invention may be formed on at least one of the main faces of a bare substrate, i.e. an uncoated substrate, or on at least one of the main faces of a substrate already coated with one or more functional coatings.

The substrate of the article according to the invention is preferably an organic glass, for example made of thermoplastic or thermosetting plastic. This substrate can be chosen from the substrates mentioned in the application WO 2008/062142, for example a substrate obtained by (co)polymerization of diethylene glycol bis(allyl carbonate), a substrate made of poly(thio)urethane or based on polyepisulfide or a substrate made of (thermoplastic) bisphenol A polycarbonate, denoted PC, or a substrate made of PMMA (polymethyl methacrylate).

Before the interference coating is deposited on the substrate, which is optionally coated, for example with an anti-abrasion and/or anti-scratch coating, it is common to subject the surface of said optionally coated substrate to a physical or chemical activation treatment intended to increase the adhesion of this coating. This pre-treatment is generally carried out under vacuum. It may be a bombardment with energetic and/or reactive species, for example an ion beam (ion pre-cleaning or IPC) or an electron beam, a corona discharge treatment, a glow discharge treatment, a UV treatment or a vacuum plasma treatment. It may also be a matter of an acidic or basic surface treatment and/or a surface treatment with solvents (water or organic solvent). These treatments are described in greater detail in application WO 2014/199103.

The article according to the invention includes an interference coating comprising at least one layer A, which forms a low-refractive-index layer of the in particular antireflection, multilayer interference coating.

According to the first embodiment of the invention, the interference coating according to the invention includes at least one layer B, deposited on the layer A and in direct contact therewith, which forms a high-refractive-index layer of the interference coating. A layer B is defined as being a layer obtained by vacuum deposition, assisted by a source of ions, of at least one metal oxide and at least one organosilicon compound B, said layer B having a refractive index higher than 1.65 and containing at least one metal oxide having a refractive index higher than or equal to 1.8.

According to the second embodiment of the invention, the interference coating according to the invention includes at least one layer C, deposited on the layer A and in direct contact therewith, which forms a low-refractive-index layer of the interference coating. A layer C is defined as being a layer comprising a silicon oxide and having a thickness smaller than or equal to 15 nm.

According to the first embodiment of the invention, the problem of weak adherence of a high-refractive-index layer based on a metal oxide deposited directly on a layer A according to the invention is solved by modifying the nature of said high-refractive-index layer, i.e. by using a layer B obtained from the same metal oxide precursor and from an additional precursor, an organosilicon compound. Such a layer B exhibits a very good adherence to the layer A, as demonstrated by the test referred to in French as the “n×10 coups” test (i.e. the “n×10 rubs” test) described in the experimental section. This material of the layer B advantageously replaces conventional high-refractive-index materials, such as zirconium or titanium dioxide, in interference coatings.

The layers A and B according to the invention form layers of silico-inorganic nature because of the use of a organosilicon compound during their production, in so far as the deposition process is such that the deposited layers comprise atoms of carbon and of silicon.

The inference coating of the invention is preferably formed on an anti-abrasion coating. The preferred anti-abrasion coatings are coatings based on epoxysilane hydrolysates comprising at least two, preferably at least three, hydrolysable groups bonded to the silicon atom. The preferred hydrolysable groups are alkoxysilane groups.

The interference coating can be any interference coating conventionally used in the field of optics, in particular of ophthalmic optics, except for the fact that it comprises at least one layer A according to the invention. The interference coating can be, without limitation, an antireflection coating or a reflective (mirror) coating, preferably an antireflection coating.

An antireflection coating is defined as a coating, deposited at the surface of an article, which improves the antireflection properties of the final article. It makes it possible to reduce the reflection of light at the article-air interface over a relatively broad portion of the visible spectrum.

As is well known, interference coatings, preferably antireflection coatings, conventionally comprise a stack of dielectric materials forming high-refractive-index (HI) layers and low-refractive-index (LI) layers.

In the present application, a layer of the interference coating is said to be a high-refractive-index layer when its refractive index is greater than 1.65, preferably greater than or equal to 1.7, better still greater than or equal to 1.8 and even better still greater than or equal to 2.0. A layer of an interference coating is said to be a low-refractive-index layer when its refractive index is less than or equal to 1.65, preferably less than or equal to 1.55, better still less than or equal to 1.50, and even better still less than or equal to 1.45.

The HI layers are conventional layers of high refractive index, well known in the art. They generally comprise one or more mineral oxides, such as, without limitation, zirconia (ZrO₂), titanium dioxide (TiO₂), tantalum pentoxide (Ta₂O₅), neodymium oxide (Nd₂O₅), hafnium oxide (HfO₂), praseodymium oxide (Pr₂O₃), praseodymium titanate (PrTiO₃), La₂O₃, Nb₂O₅, Y₂O₃, indium oxide In₂O₃ or tin oxide SnO₂. Preferred materials are TiO₂, Ta₂O₅, PrTiO₃, ZrO₂, SnO₂, In₂O₃ and their mixtures.

The LI layers are also well known and can comprise, without limitation, SiO₂, MgF₂, ZrF₄, alumina (Al₂O₃) in a small proportion, AlF₃, and their mixtures, preferably SiO₂. Use may also be made of SiOF (fluorine-doped SiO₂) layers. Ideally, the interference coating of the invention does not comprise any layer comprising a mixture of silica and alumina.

The total thickness of the interference coating is preferably less than 2 micrometers, better still less than or equal to 1.5 μm and even better still less than or equal to 1 μm. The total thickness of the interference coating is generally larger than or equal to 100 nm, preferably larger than or equal to 200 nm and better still larger than or equal respectively to each of the following values: 300 nm, 400 nm, 500 nm.

Preferably again, the interference coating, which is preferably an antireflection coating, comprises at least two layers of low refractive index (LI) and at least two layers of high refractive index (HI). The total number of layers in the interference coating is preferably less than or equal to 8 and better still less than or equal to 6.

In another embodiment, the interference coating comprises more than 8 layers.

A layer of the interference coating is defined as having a thickness of at least 1 nm. Thus, any layer having a thickness of less than 1 nm will not be considered in the count of the number of layers of the interference coating. It is not necessary for the HI and LI layers to alternate in the interference coating, although they can be alternating according to one embodiment of the invention. Two (or more) HI layers can be deposited on one another, just as two (or more) LI layers can be deposited on one another.

According to one embodiment, all the low-refractive-index layers of the interference coating are identical or different layers A. In another embodiment, the external layer of the multilayer interference coating, that is to say the layer of the interference coating furthest from the substrate in the order of stacking, is a layer A according to the invention. A layer A according to the invention is preferably deposited directly on a high-refractive-index layer.

In one embodiment, the external layer of the interference coating is a low-refractive-index layer that is preferably located directly in contact with a subjacent high-refractive-index layer. According to another embodiment, all the high-refractive-index layers of the interference coating are identical or different layers B. In certain articles according to the invention, the first layer of the interference coating, in the order of deposition, is a layer B according to the invention, which is preferably deposited on an anti-abrasion and/or anti-scratch coating.

According to one preferred embodiment, the interference coating is composed of an alternation of layers A and B according to the invention making direct contact with one another.

According to another embodiment, all the layers of the interference coating comprise at least one organosilicon compound that may be chosen from the organosilicon compounds described below.

According to one embodiment of the invention, the interference coating comprises an underlayer. It constitutes, in this case generally, the first layer of this interference coating in the order of deposition of the layers, that is to say the layer of the interference coating which is in contact with the subjacent coating (which is generally an anti-abrasion and/or anti-scratch coating) or with the substrate, when the interference coating is deposited directly on the substrate.

“Underlayer of the interference coating” is understood to mean a coating of relatively great thickness used with the aim of improving the resistance to abrasion and/or to scratches of said coating and/or to promote its adhesion to the substrate or to the subjacent coating. The underlayer according to the invention can be chosen from the underlayers described in the application WO 2010/109154. The underlayer may also be a layer A or comprise a layer A.

Preferably, the underlayer has a thickness of 100 to 500 nm. It is preferably exclusively mineral/inorganic in nature and preferably consists of silica SiO₂.

The article of the invention can be rendered antistatic by virtue of the incorporation, preferably into the interference coating, of at least one electrically conductive layer. The nature and the location in the stack of the electrically conductive layer which can be used in the invention are described in more detail in the application WO 2013/098531. It is preferably a layer with a thickness of 1 to 20 nm preferably comprising at least one metal oxide chosen from indium tin oxide (In₂O₃:Sn, indium oxide doped with tin, denoted ITO), indium oxide (In₂O₃) and tin oxide (SnO₂).

The various layers of the interference coating (including the optional antistatic layer) are preferably deposited by vacuum deposition using one of the following techniques: i) evaporation, optionally ion-beam-assisted evaporation, ii) ion-beam sputtering, iii) cathode sputtering or iv) plasma-enhanced chemical vapor deposition. These various techniques are described in the works “Thin Film Processes” and “Thin Film Processes II”, edited by Vossen and Kern, Academic Press, 1978 and 1991, respectively. A particularly recommended technique is the vacuum evaporation technique. Preferably, each of the layers of the interference coating is deposited by vacuum evaporation.

The layer B is formed from a material obtained by vacuum deposition, under assistance by a source of ions (in particular an ion beam) and preferably under ion bombardment, in particular by co-evaporation, of two categories of precursors in gaseous form: at least one metal oxide and at least one organosilicon compound B. This technique of deposition under a beam of ions makes it possible to obtain activated entities resulting from at least one organosilicon compound B and from at least one metal oxide, in the gaseous form.

In the present patent application, oxides of metaloids are considered as being metal oxides, and the generic term “metal” also designates metaloids.

The layer A is formed from a material obtained by vacuum deposition, under assistance by a source of ions (in particular an ion beam) and preferably under ion bombardment, in particular by evaporation or co-evaporation, of, depending on the circumstances, one or two categories of precursors in gaseous form: at least one organosilicon compound A and optionally at least one inorganic compound, which is preferably a metal oxide. The following description will generally make reference to the metal oxide precursor of the layer A but will also be applicable to the case where the inorganic precursor compound is not a metal oxide. This technique of deposition under a beam of ions makes it possible to obtain activated entities resulting from at least one organosilicon compound A in the gaseous form.

Preferably, the deposition of the layers A and B is carried out in a vacuum chamber comprising an ion gun directed toward the substrates to be coated, which emits, toward said substrates, a beam of positive ions generated in a plasma within the ion gun. Preferably, the ions resulting from the ion gun are particles consisting of gas atoms from which one or more electron(s) have been stripped and which are formed from a rare gas, oxygen or a mixture of two or more of these gases.

Precursors, the organosilicon compound B and the metal oxide (in the case of the layer B) or the organosilicon compound A and the optional inorganic compounds (in the case of the layer A), are introduced or pass in a gaseous state into the vacuum chamber. They are preferably conveyed in the direction of the ion beam and are activated under the effect of the ion gun.

Without wishing to be restricted by any one theory, the inventors believe that, in the case of the layer B, the ion gun induces an activation/dissociation of the precursor compound B and of the precursor metal oxide, thereby it is believed allowing M-O-Si—CHₓ bonds, M representing the metal atom of the metal oxide, to be formed.

This deposition technique using an ion gun and a gaseous precursor, sometimes denoted by “ion beam deposition”, is described in particular, with only organic precursors, in patent U.S. Pat. No. 5,508,368.

According to the invention, preferably, the only place in the chamber where a plasma is generated is the ion gun.

The ions can, if appropriate, be neutralized before they exit the ion gun. In this case, the bombardment will still be regarded as being ion bombardment. The ion bombardment causes an atomic rearrangement in and a densification of the layer being deposited, which makes it possible to tamp it down while it is in the course of being formed and has the advantage of increasing its refractive index because of its densification.

During the implementation of the process according to the invention, the surface to be treated is preferably bombarded by ions with a current density generally of between 20 and 1000 μA/cm², preferably between 30 and 500 μA/cm² and better still between 30 and 200 μA/cm², over the activated surface, and generally under a residual pressure in the vacuum chamber which can range from 6×10⁻⁵ mbar to 2×10⁻⁴ mbar and preferably from 8×10⁻⁵ mbar to 2×10⁻⁴ mbar. An argon and/or oxygen ion beam is preferably used. When a mixture of argon and oxygen is employed, the Ar/O₂ molar ratio is preferably 1, better still 0.75 and even better still 0.5. This ratio can be controlled by adjusting the gas flow rates in the ion gun. The argon flow rate generally varies from 0 to 30 sccm. Preferably, no rare gases are used. The oxygen O₂ flow rate preferably varies from 5 to 60 sccm, better still from 5 to 40 sccm and even better still from 5 to 30 sccm, and increases as the flow rate of the precursor compounds of the layers A and B increases and in proportion thereto.

As regards the layer B, the oxygen flow rate is preferably higher than or equal to 20 sccm during the co-evaporation, in order to obtain a better adherence of such a layer to a subjacent layer A.

The ions of the ion beam, preferentially resulting from an ion gun, used during the deposition of the layer A and/or B preferably have an energy ranging from 5 to 1000 eV, better still from 5 to 500 eV, preferentially from 75 to 150 eV, preferentially even from 80 to 140 eV and better still from 90 to 110 eV. The activated entities formed are typically radicals or ions.

In the event of ion bombardment during the deposition, it is possible to carry out a plasma treatment concomitant or non-concomitant with the deposition under an ion beam of the layers A and/or B. These layers are preferably deposited without the assistance of a plasma at the level of the substrates.

The deposition of the layers A and/or B, which may be carried out using identical or different methods, is done in the presence of an oxygen source when the precursor compound in question (A and/or B) does not contain (or does not contain enough) oxygen atoms and when it is desired for the corresponding layer to contain a certain proportion of oxygen. Likewise, the layers A and/or B are deposited in the presence of a nitrogen source when the precursor compound in question (A and/or B) does not contain (or does not contain enough) nitrogen atoms and when it is desired for the corresponding layer to contain a certain proportion of nitrogen. Generally, it is preferable to introduce oxygen gas with, if appropriate, a low content of nitrogen gas, preferably in the absence of nitrogen gas.

Besides the layers A and B, other layers of the interference coating can be deposited under ion bombardment as described above, that is to say by using bombardment by means of an ion beam of the layer being formed, which ions are preferably emitted by an ion gun.

The preferred method for the vaporization of the precursor materials of the layers A and B, carried out under vacuum, is physical vapor deposition, in particular vacuum evaporation, generally combined with a heating of the compounds to be evaporated. It can be deployed by using evaporation systems as diverse as a Joule-effect heat source (the Joule effect is the thermal manifestation of the electrical resistance) or an electron gun for the liquid or solid precursors, it being possible for any other device known to a person skilled in the art to also be used.

The organosilicon precursor compounds A and B are preferably introduced into the vacuum chamber in which articles according to the invention are produced in gaseous form, while controlling its flow rate. Generally, they are not vaporized in the interior of the vacuum chamber (contrary to the precursor metal oxides). The feed of the organosilicon precursor compound of the layer A or B is located ata distance from the outlet of the ion gun preferably varying from 30 to 50 cm.

Preferably, the employed metal oxides are preheated so as to reach a molten state then evaporated. They are preferably deposited by vacuum evaporation using an electron gun in order to bring about their vaporization.

The organosilicon compounds A and B, respective precursor of the layers A and B, are of organic nature and independent of each other. They may therefore be identical or different, and contain in their structure at least one silicon atom and at least one carbon atom. They preferably include at least one Si—C bond and preferably include at least one hydrogen atom. According to one embodiment, the compound A and/or B comprises at least one nitrogen atom and/or at least one oxygen atom, preferably at least one oxygen atom.

The concentration of each chemical element in the layers A and B (metal M, Si, O, C, H, N, and the like) can be determined using the RBS (Rutherford Backscattering Spectrometry) technique or ERDA (Elastic Recoil Detection Analysis).

The atomic percentage of metal atoms in the layer B preferably varies from 10 to 30%. The atomic percentage of carbon atoms in the layer B preferably varies from 10 to 20%. The atomic percentage of hydrogen atoms in the layer B preferably varies from 10 to 30%. The atomic percentage of silicon atoms in the layer B preferably varies from 10 to 20%. The atomic percentage of oxygen atoms in the layer B preferably varies from 20 to 40%.

The atomic percentage of metal atoms in the layer A preferably varies from 0 to 15%. The atomic percentage of carbon atoms in the layer A preferably ranges from 10 to 25% and more preferably from 15 to 25%. The atomic percentage of hydrogen atoms in the layer A preferably ranges from 10 to 40% and more preferably from 10 to 20%. The atomic percentage of silicon atoms in the layer A preferably ranges from 5 to 30% and more preferably from 15 to 25%. The atomic percentage of oxygen atoms in the layer A preferably ranges from 20 to 60% and more preferably from 35 to 45%.

The following compounds are nonlimiting examples of cyclic and noncyclic organic compounds A and/or B: octamethylcyclotetrasiloxane (OMCTS), decamethyl cyclopentasiloxane, dodecamethylcyclohexasiloxane, hexamethylcyclotrisiloxane, hexamethyldisiloxane (HMDSO), octamethyltrisiloxane, decamethyltetrasiloxane, dodecamethylpentasiloxane, tetraethoxysilane, vinyltrimethylsilane, hexamethyldisilazane, hexamethyldisilane, hexamethylcyclotrisilazane, vinylmethyldiethoxysilane, divinyltetramethyldisiloxane, tetramethyldisiloxane, polydimethylsiloxane (PDMS), polyphenylmethylsiloxane (PPMS) or a tetraalkylsilane, such as tetramethylsilane.

Preferably, the compound A and/or B comprises at least one silicon atom carrying at least one alkyl group, preferably a C₁-C₄ alkyl group, better still at least one silicon atom carrying one or two identical or different alkyl groups, preferably C₁-C₄ alkyl groups, for example the methyl group.

The preferred precursor compounds A and/or B comprise an Si—O—Si group, better still a divalent group of formula (3):

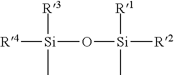

where R′¹ to R′⁴ independently denote linear or branched alkyl or vinyl groups, preferably C₁-C₄ alkyl groups, for example the methyl group, monocyclic or polycyclic aryl groups, the hydroxyl group or hydrolysable groups. Nonlimiting examples of hydrolysable groups are the following groups: H, halogen (chloro, bromo, iodo, and the like), alkoxy, aryloxy, acyloxy, —NR¹R², where R¹ and R² independently denote a hydrogen atom, an alkyl group or an aryl group, and —N(R³)—Si, where R³ denotes a hydrogen atom, a linear or branched alkyl group, preferably a C₁-C₄ alkyl group, or a monocyclic or polycyclic aryl group, preferably a monocyclic aryl group. Groups comprising an Si—O—Si chain member are not regarded as being “hydrolysable groups” within the meaning of the invention. The preferred hydrolysable group is the hydrogen atom.

According to another embodiment, the precursor compound A and/or B has the formula:

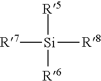

in which R′⁵, R′⁶, R′⁷ and R′⁸ independently denote hydroxyl groups or hydrolysable groups, such as OR groups, in which R is an alkyl group.

According to a first embodiment, the compound A and/or B comprises at least one silicon atom carrying two identical or different alkyl groups, preferably C₁-C₄ alkyl groups. According to this first embodiment, the compound A and/or B is preferably a compound of formula (3) in which R′¹ to R′⁴ independently denote alkyl groups, preferably C₁-C₄ alkyl groups, for example the methyl group.

Preferably, the one or more silicon atoms of the compound A and/or of the compound B when it is present do not comprise any hydrolysable group or hydroxyl group in this embodiment.

The one or more silicon atoms of the precursor compound A and/or B of the layer A and/or B are preferably solely bonded to alkyl groups and/or groups comprising an —O—Si or —NH—Si chain member, so as to form an Si—O—Si or Si—NH—Si group. The preferred precursor compounds of the layer A and/or B are OMCTS, HMDSO and decamethyltetrasiloxane.

It preferably concerns a cyclic polysiloxane of formula (4):

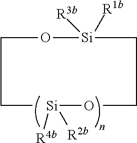

where n designates an integer ranging from 2 to 20, preferably from 3 to 8, and R^{1b} to R^{4b} independently represent linear or branched alkyl groups, preferably C₁-C₄ alkyl groups (for example the methyl group), vinyl, aryl or a hydrolysable group. The preferred members belonging to this group are octaalkylcyclotetrasiloxanes (n=3), preferably octamethylcyclotetrasiloxane (OMCTS). In some cases, the layer A and/or B results from a mixture of a certain number of compounds of formula (4), where n can vary within the limits indicated above.

According to a second embodiment, the compound A and/or B comprises, in its structure, at least one Si—X′ group, where X′ is a hydroxyl group or a hydrolysable group, which can be chosen, without limitation, from the following groups: H, halogen, alkoxy, aryloxy, acyloxy, —NR¹R², where R¹ and R² independently denote a hydrogen atom, an alkyl group or an aryl group, and —N(R³)—Si, where R³ denotes a hydrogen atom, an alkyl group or an aryl group.

According to this second embodiment of the invention, the compound A and/or B preferably comprises, in its structure, at least one Si—H group, that is to say constitutes a silicon hydride. Preferably, the silicon atom of the Si—X′ group is not bonded to more than two non-hydrolysable groups, such as alkyl or aryl groups.

Among the X′ groups, the acyloxy groups preferably have the formula —O—C(O)R⁴, where R⁴ is an aryl group, preferably a C₆-C₁₂ aryl group, optionally substituted by one or more functional groups, or an alkyl group, preferably a linear or branched C₁-C₆ alkyl group, optionally substituted by one or more functional groups and additionally being able to comprise one or more double bonds, such as the phenyl, methyl or ethyl groups, the aryloxy and alkoxy groups have the formula —O—R⁵, where R⁵ is an aryl group, preferably a C₆-C₁₂ aryl group, optionally substituted by one or more functional groups, or an alkyl group, preferably a linear or branched C₁-C₆ alkyl group, optionally substituted by one or more functional groups and additionally being able to comprise one or more double bonds, such as the phenyl, methyl or ethyl groups, the halogens are preferably F, Cl, Br or I, the X′ groups of formula —NR¹R² can denote an amino NH₂, alkylamino, arylamino, dialkylamino or diarylamino group, R¹ and R² independently denoting a hydrogen atom, an aryl group, preferably a C₆-C₁₂ aryl group, optionally substituted by one or more functional groups, or an alkyl group, preferably a linear or branched C₁-C₆ alkyl group, optionally substituted by one or more functional groups and additionally being able to comprise one or more double bonds, such as the phenyl, methyl or ethyl groups, the X′ groups of formula —N(R³)—Si are attached to the silicon atom via their nitrogen atom and their silicon atom naturally comprises three other substituents, where R³ denotes a hydrogen atom, an aryl group, preferably a C₆-C₁₂ aryl group, optionally substituted by one or more functional groups, or an alkyl group, preferably a linear or branched C₁-C₆ alkyl group, optionally substituted by one or more functional groups and additionally being able to comprise one or more double bonds, such as the phenyl, methyl or ethyl groups.

The preferred acyloxy group is the acetoxy group. The preferred aryloxy group is the phenoxy group. The preferred halogen is the Cl group. The preferred alkoxy groups are the methoxy and ethoxy groups.

In the second embodiment, the compound A and/or B preferably comprises at least one silicon atom carrying at least one linear or branched alkyl group, preferably a C₁-C₄ alkyl group, better still at least one silicon atom carrying one or two identical or different alkyl groups, preferably C₁-C₄ alkyl groups, and an X′ group (preferably a hydrogen atom) directly bonded to the silicon atom, X′ having the meaning indicated above. The preferred alkyl group is the methyl group. The vinyl group can also be used instead of an alkyl group. Preferably, the silicon atom of the Si—X′ group is directly bonded to at least one carbon atom.

Preferably, each silicon atom of the compound A and/or B is not directly bonded to more than two X′ groups, better still is not directly bonded to more than one X′ group (preferably a hydrogen atom) and better still each silicon atom of the compound A and/or B is directly bonded to a single X′ group (preferably a hydrogen atom). Preferably, the compound A and/or B comprises an Si/O atomic ratio equal to 1. Preferably the compound A and/or B comprises a C/Si atomic ratio <2, preferably ≤1.8, better still ≤1.6 and even better still ≤1.5, ≤1.3 and optimally equal to 1. Preferably again, the compound A and/or B comprises a C/O atomic ratio equal to 1. According to one embodiment, the compound A and/or B does not comprise an Si—N group and better still does not comprise a nitrogen atom.

The one or more silicon atoms of the precursor compound A and/or B are preferably solely bonded to alkyl or hydrogen groups and/or groups comprising an —O—Si or —NH—Si chain member, so as to form an Si—O—Si or Si—NH—Si group. In one embodiment, the compound A and/or B comprises at least one Si—O—Si—X′ group or at least one Si—NH—Si—X′ group, X′ having the meaning indicated above and preferably representing a hydrogen atom.

According to this second embodiment, the compound A and/or B is preferably a compound of formula (3) in which at least one of R′¹ to R′⁴ denotes an X′ group (preferably a hydrogen atom), X′ having the meaning indicated above.

According to this second embodiment, the compound A and/or B is preferably a cyclic polysiloxane of formula (5):

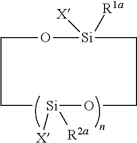

where X′ has the meaning indicated above and preferably represents a hydrogen atom, n designates an integer ranging from 2 to 20, preferably from 3 to 8, and R^{1a} and R^{2a} independently represent an alkyl group, preferably a C₁-C₄ alkyl group (for example the methyl group), vinyl, aryl or a hydrolysable group. Nonlimiting examples of hydrolysable X′ groups are the chloro, bromo, alkoxy, acyloxy, aryloxy and H groups. The commonest members belonging to this group are the tetra-, penta- and hexaalkylcyclotetrasiloxanes, preferably the tetra-, penta- and hexamethylcyclotetrasiloxanes, 2,4,6,8-tetramethylcyclotetrasiloxane (TMCTS) being the preferred compound. In some cases, the layer A and/or B results from a mixture of a certain number of compounds having the above formula, where n can vary within the limits indicated above.

According to another embodiment, the compound A and/or B is a linear alkylhydrosiloxane, better still a linear methylhydrosiloxane, such as, for example, 1,1,1,3,5,7,7,7-octamethyltetrasiloxane, 1,1,1,3,5,5,5-heptamethyltrisiloxane or 1,1,3,3,5,5-hexamethyltrisiloxane.

The following compounds are nonlimiting examples of cyclic and non-cyclic organic precursor compounds A and/or B in accordance with the second embodiment: 2,4,6,8-tetramethylcyclotetrasiloxane (TMCTS of formula (1)), 2,4,6,8-tetraethylcyclotetrasiloxane, 2,4,6,8-tetraphenylcyclotetrasiloxane, 2,4,6,8-tetraoctylcyclotetrasiloxane, 2,2,4,6,6,8-hexamethylcyclotetrasiloxane, 2,4,6-trimethylcyclotrisiloxane, cyclotetrasiloxane, 1,3,5,7,9-pentamethylcyclopentasiloxane, 2,4,6,8,10-hexamethylcyclohexasiloxane, 1,1,1,3,5,7,7,7-octamethyltetrasiloxane, 1,1,3,3,5,5-hexamethyltrisiloxane, tetramethyldisiloxane, tetraethoxysilane, vinylmethyldiethoxysilane, a hexamethylcyclotrisilazane, such as 3,4,5,6-hexamethylcyclotrisilazane or 2,2,4,4,6,6-hexamethylcyclotrisilazane, 1,1,1,3,5,5,5-heptamethyltrisiloxane, tris(trimethylsiloxy)silane (of formula (2)), 1,1,3,3-tetramethyldisilazane, 1,2,3,4,5,6,7,8-octamethylcyclotetrasilazane, nonamethyltrisilazane, tris(dimethylsilyl)amine or hexamethyldisilazane.

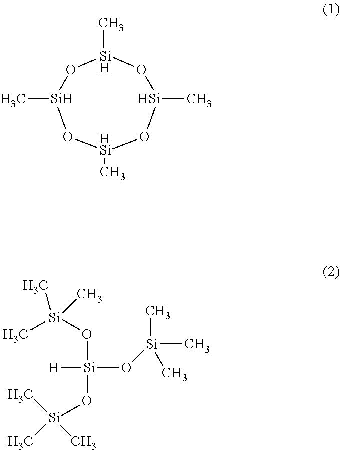

The precursor metal oxide of the layer B is preferably a high-refractive-index metal oxide, which expression was defined above. It may be chosen from metal oxides and mixtures thereof suitable for the high-refractive-index layers as described above, or from substoichiometric metal oxides such as a substoichiometric titanium or zirconium oxide, of respective formulae TiOx and ZrOx, with x<2, x preferably varying from 0.2 to 1.2. It is preferably a question of the oxide ZrO₂ or of a substoichiometric zirconium oxide such as the compounds ZrO, Zr₂O₃, or Zr₃O₅. The precursor metal oxide is preferably a substoichiometric zirconium oxide such as ZrO.

The layer B may be formed from one or more metal oxides, for example a mixture of ZrO and Zr₂O₃, in particular by co-evaporation of these compounds.

Preferably, the refractive index of the layer B is higher than or equal to at least one of the following values: 1.7, 1.8, 1.9, 2.0, 2.05 and ideally higher than or equal to 2.1.

The layer B of the final article contains at least one metal oxide having a refractive index higher than or equal to 1.8. This metal oxide may be the same as the precursor metal oxide used to form the layer B and described above or be different therefrom, insofar as the deposition process of the layer B may induce a modification of the precursor metal oxide such as an oxidation. It is preferably a question of a zirconium oxide, in particular the compound ZrO₂, or of a hafnium oxide.

The use of zirconium oxide is advantageous due to the high refractive index of this metal oxide. The refractive index of the oxide ZrO₂ is effectively of the order of 2.15 at 632.8 nm. Thus, the layer B can retain a high refractive index (preferably 1.8), even if the zirconium oxide is mixed with an organosilicon compound B of lower refractive index.

The use of at least one organosilicon compound B to form the layer B, which preferably comprises Si—C and optionally Si—O bonds, makes it possible to benefit from improved thermomechanical properties with respect to the conventional materials of high refractive index, such as TiO₂ or ZrO₂, in particular, the thermal resistance and the scratch resistance of the substrates coated with the layers B according to the invention are improved, levels hitherto inaccessible with conventional technologies, such as the ion-assisted deposition of purely inorganic layers, being achieved therewith while a high refractive index and a high transparency are maintained.

According to one embodiment of the invention, the layer B comprises more than 80% by weight, preferably more than 90% by weight, of compounds resulting from compound B and metal oxide according to the invention, with respect to the total weight of the layer B. According to one embodiment, the layer B is exclusively formed by vacuum deposition under ion bombardment of at least one metal oxide and of at least one organosilicon compound B, with the exclusion of any other precursor.

Preferably, the layer B contains from 5 to 90% by weight of metal oxides with respect to the weight of the layer B. Also preferably, the layer B contains from 5 to 70% by weight of organosilicon compounds B with respect to the weight of the layer B.

According to one preferred embodiment, the layer A is not formed from inorganic (mineral) precursor compounds such as mineral oxides and therefore does not contain any inorganic compounds such as metal oxides. In this case, the layer A is a layer that preferably contains only organosilicon compounds.

In one embodiment, when they are present, the inorganic precursor compounds of the layer A (generally metal oxides having a refractive index lower than or equal to 1.65), are in a proportion such that the layer A contains less than 30% by weight of inorganic compounds with respect to the weight of the layer A, preferably less than 20%, also preferably less than 10%, and better still less than 5%. Preferably, the amount of inorganic compounds or metal oxides in the layer A is smaller than 10% by weight with respect to the weight of the layer A, better still smaller than 5% and even better still smaller than 1%. The proportion of inorganic compound and organic compound in the layer A may be determined, for example, using the known refractive indices of the inorganic compounds and of the organic compounds and by measuring the thickness and the reflection of the layer A. The proportion of organic compound in the layer A may be determined by interpolation from the refractive index of the layer A, using as reference points the refractive index of a layer made of the organic compound and the refractive index of a layer made of the inorganic compound.

Preferably, the layer A contains more than 70% by weight of organosilicon compounds A with respect to the weight of the layer A, better still more than 80%, even better still more than 90% and ideally 100%.

The refractive index of the layer A is lower than or equal to 1.65 and preferably lower than or equal to 1.50. According to embodiments of the invention the refractive index of the layer A is higher than or equal to 1.45, more preferably higher than 1.47, even more preferably higher than or equal to 1.48 and ideally higher than or equal to 1.49.

When it is formed from an inorganic precursor compound, the layer A of the final article preferably contains at least one inorganic compound.

This inorganic compound may be the same as the inorganic precursor compound used to form the layer A and described above or be different therefrom, insofar as the deposition process of the layer A may induce a modification of the inorganic precursor compound such as an oxidation. It is preferably a question of a silicon oxide, in particular the compound SiO₂.

According to one embodiment of the invention, the layer A comprises more than 80% by weight, preferably more than 90% by weight, of compounds resulting from the compound A, with respect to the total weight of the layer A. According to one embodiment, the layer A is exclusively formed by vacuum deposition under ion bombardment of at least one organosilicon compound A and optionally of at least one inorganic compound, with the exclusion of any other precursor.

Preferably, the layer A and/or B does not comprise a fluorinated compound. Also preferably, the layer A and/or B does not contain a distinct metal-oxide or inorganic-compound phase, depending on the circumstances. As the layers A and B are formed by vacuum deposition, they do not comprise organosilicon-compound hydrolysate and thus differ from sol-gel coatings obtained by wet processing.

The layer A and/or B preferably possesses a thickness ranging from 20 to 500 nm, also preferably from 25 to 250 nm and better still from 30 to 200 nm. When it forms the external layer of the interference coating, the layer A preferably has a thickness ranging from 60 to 200 nm. The duration of the deposition process, the flow rates and the pressures are adjusted so as to obtain the desired coating thicknesses.

The layer A and/or B preferably possesses a static contact angle with water of greater than or equal to 70°, better still of greater than or equal to 80° and even better still of greater than or equal to 90°, preferably varying from 70 to 95°.

In one embodiment, the article according to the invention possesses a layer B making direct contact with the layer A, and a layer D comprising at least one metal oxide having a refractive index higher than or equal to 1.8 deposited on the layer B and in direct contact therewith.

According to another embodiment, the article according to the invention furthermore comprises a layer A according to the invention forming the external layer of the interference coating and optionally making direct contact with said layer D.

The layer D is a high-refractive-index layer (preferably of refractive index 1.8), the metal oxide of which, which has a refractive index higher than or equal to 1.8, may be chosen from the high-refractive-index metal oxides described above, in particular those envisioned for the layer B. It is preferably a question of a zirconium oxide such as ZrO₂ or a substoichiometric zirconium oxide such as the compounds ZrO, Zr₂O₃, or Zr₃O₅, ideally ZrO₂. The precursor metal oxide of the layer D is preferably a substoichiometric zirconium oxide such as ZrO.

The refractive index of the layer D or of the precursor metal oxide of the layer D is preferably higher than or equal to 1.9, better still 1.95, even better still 2.0 and ideally 2.1. The layer D, when it is present, has a thickness ranging preferably from 5 to 300 nm. When the layer D is present, the sum of the thicknesses of the layers D and B preferably ranges from 50 to 200 nm, more preferably from 75 to 175 nm and even more preferably from 100 to 175 nm.

The layer D may be deposited using the same techniques as those presented for the layers A and B. Thus, the layer D is preferably vacuum deposited, typically by evaporation, preferably under assistance from a source of ion, the ions preferably being generated by an ion gun.

Preferably, the layer D is not formed from organic precursor compounds, in particular organosilicon compounds, and therefore does not contain organic compounds such as organosilicon compounds. In this case, the layer D is a layer of inorganic nature, which preferably contains only metal oxides. Preferably, the amount of organic compounds or organosilicon compounds in the layer D is smaller than 10% by weight with respect to the weight of the layer D, better still smaller than 5% and even better still smaller than 1%.

Preferably, the layer D is formed following the layer B simply by stopping the injection into the vacuum chamber of the organosilicon compound B when the deposition of the layer B is finished, the injection of the metal oxide being continued. In this case, the precursor metal oxide of the layer B and that of the layer D are identical. This deposition method is advantageous because no defect in the adhesion between the layers B and D is then observable.

From the point of view of optical performance, the fact of forming a layer D based on high-refractive-index metal oxide, preferably under ion assistance and preferably free from organic compound allows a layer of high refractive index to be obtained and the drop in optical performance related to the lower refractive index of the subjacent co-evaporated layer B that results from the use of an organosilicon compound to be compensated for.

According to the second embodiment of the invention, the interference coating includes at least one layer C, deposited on the layer A and in direct contact therewith, said layer C comprising a silicon oxide and having a thickness smaller than or equal to 15 nm, and making direct contact with a layer E comprising at least one metal oxide having a refractive index higher than or equal to 1.8.

The layer C is a low-refractive-index layer (refractive index≤1.65), the refractive index of which is preferably lower than or equal to 1.50. In some embodiments of the invention the refractive index of the layer C is generally higher than or equal to 1.45, more preferably higher than 1.47, even more preferably higher than or equal to 1.48 and ideally higher than or equal to 1.49.

The silicon oxide of the layer C may be chosen from silica (SiO₂) and substoichiometric silicon oxides, of formula SiOx, with x<2, x preferably varying from 0.2 to 1.2. It is preferably a question of the oxides SiO₂ or SiO or of mixtures thereof, ideally SiO₂.

The layer C preferably contains at least 50 wt % silicon oxides, with respect to the total weight of the layer C, more preferably 75 wt % or more, even more preferably 90 wt % or more and ideally 95 wt % or more. According to one preferred embodiment, the layer C is a layer formed exclusively from silicon oxides.

The layer C preferably is a silica-based layer containing at least 50 wt % silica, with respect to the total weight of the layer C, more preferably 75 wt % or more, even more preferably 90 wt % or more and ideally 95 wt % or more. According to one preferred embodiment, the layer C is a layer formed exclusively from silica.

The layer C, when it is present, is a thin layer having a thickness preferably smaller than or equal to 10 nm, which preferably varies from 2 to 10 nm, and better still from 5 to 10 nm.

The layer E is a high-refractive-index layer (preferably of refractive index 1.8), the metal oxide of which, which has a refractive index higher than or equal to 1.8, may be chosen from the high-refractive-index metal oxides described above, in particular those envisioned for the layer B. It is preferably a question of a zirconium oxide such as the oxide ZrO₂ or a substoichiometric zirconium oxide such as the compounds ZrO, Zr₂O₃, or Zr₃O₅, ideally ZrO₂. The precursor metal oxide of the layer E is preferably a substoichiometric zirconium oxide such as ZrO.

The refractive index of the layer E or of the precursor metal oxide of the layer E is preferably higher than or equal to 1.9, better still 1.95, even better still 2.0 and ideally 2.05.

The layer E, when it is present, preferably has a thickness ranging from 5 to 300 nm and better still from 50 to 300 nm. When the layer E is present, the sum of the thicknesses of the layers E and C preferably ranges from 30 to 315 nm, more preferably from 75 to 175 nm and even more preferably from 100 to 175 nm.

The layer C or E may be deposited using the same techniques as those presented for the layers A and B. Thus, the layers C and/or E are preferably vacuum deposited, typically by evaporation, preferably under assistance from a source of ion, better still from an ion gun.

Preferably, the layers C and/or E are not formed from organic precursor compounds, in particular organosilicon compounds and therefore do not contain organic compounds such as organosilicon compounds. In this case, the layers C and/or E are layers of inorganic nature, which preferably contain only metal oxides. Preferably, the amount of organic compounds or organosilicon compounds in the layer C or E is smaller than 10% by weight with respect to the weight of the layer C or E, better still smaller than 5% and even better still smaller than 1%.

As was explained above, it is difficult to make a layer based on high-refractive-index metal oxides E adhere directly to a layer A according to the invention.

The second embodiment of the invention allows this problem of adherence to be solved by inserting between the layer A and the high-refractive-index layer E a thin silicon-oxide-based layer. The first embodiment of the invention, using a high-refractive-index layer modified by an organosilicon compound, in the present case a layer B, is however preferred, because it allows an article having superior abrasion-resistance and thermomechanical properties to be obtained.

The nature of the precursor compounds employed, their respective amounts (which can be modulated by adjusting the flow rates evaporated) and the deposition conditions, in particular the duration of the deposition, are examples of parameters that a person skilled in the art will be able to vary in order to obtain an interference coating comprising the layers A to E and having all of the desired properties, in particular with the help of the examples of the present patent application.

Among its advantageous properties, the article according to the invention possesses an increased resistance to bending. This results from the nature of the layers A and B of the invention, which possess greater elongations at break than those of inorganic layers and can undergo deformations without cracking.

The critical temperature of a coated article according to the invention is preferably greater than or equal to 70° C., better still greater than or equal to 80° C. and even better still greater than or equal to 90° C. In the present patent application, the critical temperature of an article or a coating is defined as being the temperature starting from which cracks are observed to appear in the stack present at the surface of the substrate, which results in degradation of the coating. This high critical temperature is due to the presence of the layer A (and of the layer B when it is present) on the surface of the article, as demonstrated in the experimental part. Furthermore, the layers A and B obtained possess a poorer ability to become loaded with water than evaporated inorganic layers. The stability of optical properties of the layers A and B obtained according to the invention over time is excellent.

Because of their improved thermomechanical properties, the layers A and B may especially be applied to a single face of a semi-finished lens, generally its front face, the other face of this lens still needing to be machined and treated. The stack present on the front face of the lens will not be degraded by the increase in temperature generated by the treatments to which the back face will be subjected during the curing of the coatings which will have been deposited on this back face or any other action liable to increase the temperature of the lens.

Preferably, the average reflection factor in the visible region (400-700 nm) of an article coated with an interference coating according to the invention, denoted Rₘ, is less than 2.5% per face, better still less than 2% per face and even better still less than 1% per face of the article. In an optimal embodiment, the article comprises a substrate, the two main surfaces of which are coated with an interference coating according to the invention and which exhibits a total Rₘ value (cumulative reflection due to the two faces) of less than 1%. Means for achieving such Rₘ values are known to a person skilled in the art.

The light reflection factor Rᵥ of an interference coating according to the invention is less than 2.5% per face, preferably less than 2% per face, better still less than 1% per face of the article, better still ≤0.75% and even better still ≤0.5%.

In the present patent application, the “average reflection factor” Rₘ (average of the spectral reflection over the entire visible spectrum between 400 and 700 nm) and the “light reflection factor” Rᵥ are as defined in the standard ISO 13666:1998 and are measured according to the standard ISO 8980-4.

In some applications, it is preferable for the main surface of the substrate to be coated with one or more functional coatings prior to the deposition of the interference coating. These functional coatings, which are conventionally used in optics, may, without limitation, be a primer layer for improving the shock-resistance and/or adhesion of subsequent layers in the final product, an anti-abrasion and/or anti-scratch coating, a polarized coating, a photochromic coating, an electrochromic coating or a tinted coating, and may in particular be a primer layer coated with an anti-abrasion and/or anti-scratch layer. The last two coatings are described in more detail in the applications WO 2008/015364 and WO 2010/109154.

The article according to the invention may also comprise coatings, formed on the interference coating, capable of modifying the surface properties of the interference coating, such as a hydrophobic coating and/or oleophobic coating (anti-smudge top coat) or an anti-fogging coating. These coatings are preferably deposited on the external layer of the interference coating, which may be a layer A. Their thickness is in general smaller than or equal to 10 nm, preferably from 1 to 10 nm, and better still from 1 to 5 nm. They are described in the applications WO 2009/047426 and WO 2011/080472 respectively.

Typically, an article according to the invention comprises a substrate successively coated with a layer of adhesion and/or shock-resistant primer, with an anti-abrasion and/or anti-scratch coating, with an optionally antistatic interference coating comprising in particular a layer A and a layer B or C according to the invention, and with a hydrophobic and/or oleophobic coating.

The invention also relates to a process for manufacturing an article such as defined above, comprising at least the following steps:
supplying an article comprising a substrate having at least one main surface,
depositing, on said main surface of the substrate, a layer A having a refractive index lower than or equal to 1.65,
depositing on said layer A:

either a layer B having a refractive index higher than 1.65 and containing at least one metal oxide having a refractive index higher than 1.8, and optionally depositing directly on said layer B a layer D comprising at least one metal oxide having a refractive index higher than or equal to 1.8,

or a layer C comprising a silicon oxide and having a thickness lower than or equal to 15 nm, and depositing directly on said layer C a layer E comprising at least one metal oxide having a refractive index higher than or equal to 1.8,

collecting an article comprising a substrate having a main surface coated with an interference coating comprising, in order starting from the substrate, a layer A making direct contact with a layer B or a layer A making direct contact with a layer C making direct contact with a layer E,

said layer A having been obtained by vacuum deposition, assisted by a source of ions, of at least one organosilicon compound A, and said layer B, when it is present, having been obtained by vacuum deposition, assisted by a source of ions, and at least one metal oxide and at least one organosilicon compound B.

The invention is illustrated in a nonlimiting way by the following examples.

### EXAMPLES

### 1. General Procedures

The articles employed in the examples comprise an Orma® Essilor lens substrate with a diameter of 65 mm, with a power of −2.00 diopters and with a thickness of 1.2 mm, coated on its concave face with the shock-resistant primer coating and with the anti-scratch and anti-abrasion coating (hard coat), which are disclosed in the experimental section of the application WO 2010/109154, and an antireflection interference coating comprising a layer A according to the invention and a layer B or C according to the invention.

The vacuum deposition reactor is a Leybold LAB1100+ device equipped with an electron gun for the evaporation of the precursor materials, with a thermal evaporator, with a KRI EH 1000 F ion gun (from Kaufman & Robinson Inc.), for the preliminary phase of preparation of the surface of the substrate by argon ions (IPC) and also for the deposition of the layers under ion bombardment (IAD), and with a system for the introduction of liquid, which system is used when the organosilicon precursor compound in particular of the layer A and/or B is a liquid under standard temperature and pressure conditions (case of decamethyltetrasiloxane). This system comprises a tank containing the liquid precursor compound of the layer in question, resistance heaters for heating the tank, tubes connecting the tank of liquid precursor to the vacuum deposition device and a vapor flowmeter from MKS (MKS1150C), brought to a temperature of 30-120° C. during its use, depending on the flow rate of vaporized decamethyltetrasiloxane, which preferably varies from 0.01 to 0.8 g/min (1 to 50 sccm) (the temperature is 120° C. for a flow rate of 0.3 g/min (20 sccm) of decamethyltetrasiloxane).

The decamethyltetrasiloxane vapor exits from a copper tube inside the machine, at a distance of about 30 cm from the ion gun. Flows of oxygen and optionally of argon are introduced into the ion gun. Preferably, neither argon nor any other rare gas is introduced into the ion gun.

The layers A, B and/or D according to the invention are formed by vacuum evaporation assisted by a beam of oxygen and optionally argon ions during the deposition (evaporation source: electron gun) of decamethyltetrasiloxane (layers A, B) supplied by Sigma-Aldrich and of a substoichiometric zirconium oxide (ZrO) supplied by Umicore (layers B, D).

Unless otherwise indicated, the thicknesses mentioned in the present patent application are physical thicknesses. Several samples of each eyeglass were prepared.

### 2. Procedures

The process for the preparation of the optical articles according to the invention comprises the introduction of the substrate, coated with the primer coating and with the anti-abrasion coating which are defined above, into the vacuum deposition chamber; the preheating of the tank, the pipes and the vapor flowmeter to the chosen temperature (˜15 min), a primary pumping stage, then a secondary pumping stage for 400 seconds making it possible to obtain a high vacuum (˜2×10⁻⁵ mbar, pressure read from a Bayard-Alpert gauge); a stage of activation of the surface of the substrate by a beam of argon ions (IPC: 1 minute, 100 V, 1 A, the ion gun remaining in operation at the end of this step), then the deposition by evaporation of an antireflection coating comprising at least one layer A.

Deposition of a layer A according to the invention: The ion gun having been started with argon, oxygen is added to the ion gun with a programmed flow rate, the desired anode current (3 A) is programmed and the argon flow is optionally halted, depending on the deposition conditions desired. Generally, the process according to the invention is carried out with oxygen (flow rate of O₂ in the ion gun level with the ion source: 20 sccm) introduced into the ion gun, in the absence of rare gas. The decamethyltetrasiloxane is introduced into the chamber (flow rate of injection: 20 sccm). The supply of this compound is stopped once the desired thickness has been obtained, then the ion gun is turned off. A layer B or C according to the invention is then deposited directly on the layer A.

Deposition of a layer B according to the invention: The substoichiometric zirconium oxide ZrO (inorganic precursor) is preheated so as to reach a molten state then evaporated using an electron gun, the shutter of the ion gun and that of the electron gun being opened simultaneously (flow rate of O₂ in the ion gun level with the ion source: 20 sccm, no argon flow, anode current: 3 A). At the same time, decamethyltetrasiloxane is introduced into the deposition chamber in gaseous form, at a controlled injection flow rate of 7 sccm. The obtained layer has a refractive index of 1.8.

Deposition of a layer C according to the invention (silica layer): this was carried out conventionally by vacuum evaporation of SiO₂ without ion assistance.

Deposition of a layer D according to the invention: The layers D were obtained by evaporation of zirconium oxide under ion assistance (flow rate of O₂ in the ion gun level with the ion source: 20 sccm, no argon flow, anode current: 3 A), and possess a refractive index of 2.08.

The other metal-oxide layers (containing no organosilicon compound) were deposited conventionally by vacuum evaporation of the right metal oxide (zirconium oxide, SiO₂ etc.), without ion assistance.

The thickness of the layers deposited was controlled in real-time by means of a quartz microbalance, the rate of deposition being modified, if need be, by adjusting the current of the electron gun. Once the desired thickness is obtained, the shutter or shutters were closed, the ion and electron gun or guns were switched off and the gas flows (oxygen, optionally argon and decamethyltetrasiloxane vapors) were halted.

A final venting step was carried out once the deposition of the stack had finished.

A plurality of comparative examples were produced, with the one or more layers A according to the invention replaced with layers of SiO₂, and with the layers B and D according to the invention replaced with layers of ZrO₂. Thus, comparative example 1 differs from examples 1 to 4 in the removal of all the organosilicon compounds from the layers of the antireflection coating, and comparative example 5 differs from the example 5 in the removal of all the organosilicon compounds from the layers of the antireflection coating.

### 3. Characterizations

The critical temperature of the article is measured 24 hours and/or one week after its preparation, in the way indicated in the patent application WO 2008/001011.

Unless otherwise indicated, the refractive indices to which reference is made in the present invention are expressed for a wavelength of 632.8 nm and were measured by ellipsometry at a temperature of 20-25° C.

The bending resistance test, described in patent application WO 2013/098531, allowed the capacity of an article having a curvature to undergo a mechanical deformation to be evaluated. The forces applied in this test were representative of the forces applied at an opticians when fitting the eyeglass, i.e. when the eyeglass is “compressed” in order to be inserted into a metal frame. The result of the test, which was carried out one month after production of the eyeglasses, is the critical deformation D in mm that the eyeglass can undergo before cracks appear. The higher the value of the deformation, the better the resistance to applied mechanical deformation. Generally, interference coatings according to the invention have critical deformation values ranging from 0.7 to 1.9 mm, preferably from 0.8 to 1.6 mm and more preferably from 0.9 to 1.5 mm.

The adhesion properties of the whole of the interference coating to the substrate were verified on the convex face of the lens by means of the test commonly referred to in

French as the “n×10 coups” test (i.e. the “n×10 rubs” test) described in international patent applications WO 2010/109154 and WO 99/49097 (N.B. in the latter this test is referred to as the “n 10 blow” test). The test consists in noting the number of cycles that the lens was able to be subjected to before the appearance of a defect. Therefore, the higher the value obtained in the n×10 rubs test, the better the adhesion of the interference coating to the substrate.

The abrasion resistance of the article was evaluated by determining Bayer ASTM (Bayer sand) values for substrates coated with the antireflection coating, using the methods described in patent application WO 2008/001011 (standard ASTM F 735.81). The higher the value obtained in the Bayer test, the higher the resistance to abrasion. Thus, the Bayer ASTM (Bayer sand) value was deemed to be good when it was higher than or equal to 3.4 and lower than 4.5 and excellent for values of 4.5 or more.

Hardness, or scratch resistance, was evaluated by virtue of the test referred to in French as the “paille de fer (pdf manuel, ou testa à la laine d′acier)” test i.e. the “manual steel wool” test, such as described in patent application WO 2008/062142. The higher the score obtained (score ranging from 1 to 5), the lower the scratch resistance of the eyeglass.

### 4. Results

The tables below collate the optical and mechanical performance of comparative articles or various articles according to the invention and the deposition conditions of the various layers and their thicknesses.

| Example 1 | | Comparative example C1 | |
|---|---|---|---|
| Substrate + primer + hard coat | | Substrate + primer + hard coat | |
| ZrO₂ | 13.5 nm | ZrO₂ | 13.5 nm |
| Layer A* | 412 nm | SiO₂ | 412 nm |
| Layer B* | 70-90 nm | ZrO₂ | 153 nm |
| ZrO₂ (Layer D)* | 60-70 nm | SiO₂ | 235 nm |
| SiO₂ | 235 nm | ZrO₂ | 277 nm |
| ZrO₂ | 277 nm | SiO₂ | 120 nm |
| SiO₂ | 120 nm | | |
| Example 2 | | Example 4 | |
| Substrate + primer + hard coat | | Substrate + primer + hard coat | |
| Layer B* | 13.5 nm | ZrO₂ | 13.5 nm |
| Layer A* | 412 nm | Layer A* | 412 nm |
| Layer B* | 153 nm | Layer B* | 153 nm |
| Layer A* | 235 nm | SiO₂ | 235 nm |
| Layer B* | 277 nm | ZrO₂ | 277 nm |
| Layer A* | 120 nm | SiO₂ | 120 nm |
| Example 3 | | Comparative example C2 | |
| Substrate + primer + hard coat | | Substrate + primer + hard coat | |
| ZrO₂ | 13.5 nm | ZrO₂ | 13.5 nm |
| Layer A* | 412 nm | Layer A* | 412 nm |
| Layer B* | 70-90 nm | ZrO₂ | 153 nm |
| ZrO₂ (Layer D)* | 60-70 nm | SiO₂ | 235 nm |
| SiO₂ | 235 nm | ZrO₂ | 277 nm |
| ZrO₂ | 277 nm | SiO₂ | 120 nm |
| Layer A* | 120 nm | | |
| Example 5 | | Comparative example C3 | |
| Substrate + primer + hard coat | | Substrate + primer + hard coat | |
| ZrO₂ | 47 nm | ZrO₂ | 47 nm |
| SiO₂ | 50 nm | SiO₂ | 50 nm |
| ZrO₂ | 54 nm | ZrO₂ | 54 nm |
| SiO₂ | 69 nm | SiO₂ | 69 nm |
| ZrO₂ | 44 nm | ZrO₂ | 44 nm |
| Layer A* | 61 nm | SiO₂ | 61 nm |
| Layer B* | 25-30 nm | ZrO₂ | 53 nm |
| ZrO₂ (Layer D)* | 25 nm | SiO₂ | 132 nm |
| Layer A* | 132 nm | | |

Layer A: Decamethyltetrasiloxane.
Layer B: Decamethyltetrasiloxane + ZrO₂.
*Deposition under ion assistance.

Example 6
Substrate + primer + hard coat

| | |
|---|---|
| ZrO₂ | 13.5 nm |
| Layer A* | 412 nm |
| Layer C | 7-10 nm |
| ZrO₂ | 153 nm |
| SiO₂ | 235 nm |
| ZrO₂ | 277 nm |
| SiO₂ | 120 nm |

Layer A: Decamethyltetrasiloxane.
Layer C: SiO₂
*Deposition under ion assistance.

| | | | | | | Resistance |
|---|---|---|---|---|---|---|
| | | | | Critical | Critical | to bending, |
| | Bayer | n × 10 | Steel | T | T | deformation |
| Exam- | ASTM | rubs | wool | [° C.] at | [° C.] at | in mm before |
| ple | test | test | test | t + 24 h | t + 1 week | cracking |
| 1 | 6.7 | 13 | 3 | 70 | 60 | 0.69 |
| C1 | 6.8 | 13 | 3 | 60 | 50 | 0.32 |
| C2 | | 3-6 | | | | |
| 2 | 5.5 | 13 | 1 to 3 | 120 | 120 | 1.45 |
| 3 | 6.2 | 13 | 3 | 80 | 70 | 0.91 |
| 4 | 7.0 | 13 | 3 | 70 | 60 | 0.65 |
| 5 | 5.1 | 13 | 1 | 90 | 90 | 1.02 |
| C3 | 1.6 | 13 | 3 | 70 | 50 | 0.44 |
| 6 | 6.8 | 13 | 3 | 60 | 60 | 0.66 |

The article of comparative example 2, possessing a layer of ZrO₂ deposited directly on a layer A according to the invention, exhibits substantial cracking over all the area of the eyeglass, independently of the deposition parameters of the layer A. The inventors believe, without however wishing to be limited to any one theory, that the fragility of this structure is located at the interface between the layer A and the subsequently deposited ZrO₂ layer. The n×10 rubs test revealed a substantial problem with adherence.

The articles of examples 1 to 5 exhibit no cracking at the end of their production and performed well in the various durability tests carried out. They have higher critical temperatures and bending resistances 2 to 4.5 times higher than the articles of the comparative examples the antireflection layers of which contain no organosilicon compound.

The use of a layer D obtained by evaporation of zirconium oxide in examples 1, 3 and 5 is very advantageous from an optical point of view. Its high refractive index (n=2.08 at 632.8 nm) in particular allows the loss of refractive index in the subjacent layer B (n=1.8 at 632.8 nm) associated with the use of an organosilicon compound to be compensated for.

The best results in terms of bending resistance and critical temperature were obtained with example 2, all the layers of the antireflection stack of which were formed under ion assistance and were obtained from an organosilicon compound and a metal oxide (SiO₂ for the low-refractive-index layers, ZrO₂ for the high-refractive-index layers).

1.-15. (canceled)

16. An article comprising a substrate having at least one main surface coated with an interference coating comprising, in order starting from the substrate:
a layer A obtained by vacuum deposition, assisted by a source of ions, of at least one organosilicon compound A, said layer A having a refractive index lower than or equal to 1.65, and, making direct contact with this layer A; and
either:
a layer B obtained by vacuum deposition, assisted by a source of ions, of at least one metal oxide and at least one organosilicon compound B, said layer B having a refractive index higher than 1.65 and containing at least one metal oxide having a refractive index higher than or equal to 1.8; or
a layer C comprising a silicon oxide and having a thickness lower than or equal to 15 nm, making direct contact with a layer E comprising at least one metal oxide having a refractive index higher than or equal to 1.8.

17. The article of claim 16, wherein the deposition assisted by a source of ions is an ion bombardment.

18. The article of claim 16, wherein the compound A comprises at least one divalent group of formula: 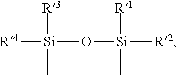
where R′¹ to R′⁴ independently denote alkyl, vinyl, aryl or hydroxyl groups or hydrolysable groups, or in that the compound A corresponds to the formula: 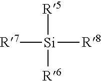
in which R′⁵, R′⁶, R′⁷ and R′⁸ independently denote hydroxyl groups or hydrolysable groups.

19. The article of claim 18, wherein the hydrolyzable groups are OR groups, in which R is an alkyl group.

20. The article of claim 16, wherein the compound A is chosen from octamethylcyclotetrasiloxane, decamethyltetrasiloxane, 2,4,6,8-tetramethylcyclotetrasiloxane, hexamethyldisiloxane, decamethylcyclopentasiloxane and dodecamethylpentasiloxane.

21. The article of claim 16, wherein said layer A is not formed from inorganic precursor compounds.

22. The article of claim 16, wherein the layer A has a thickness ranging from 20 to 500 nm.

23. The article of claim 16, wherein it possesses a layer B deposited on the layer A and in direct contact therewith, the compound B of which includes at least one divalent group of formula: 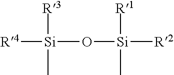
where R′¹ to R′⁴ independently denote alkyl, vinyl, aryl or hydroxyl groups or hydrolysable groups, or in that the compound B corresponds to the formula: 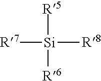
in which R′⁵, R′⁶, R′⁷ and R′⁸ independently denote hydroxyl groups or hydrolysable groups.

24. The article of claim 16, wherein it possesses a layer B deposited on the layer A and in direct contact therewith, the metal oxide having a refractive index higher than or equal to 1.8 of which is a zirconium oxide or a hafnium oxide.

25. The article of claim 16, wherein it possesses said layer B making direct contact with said layer A, and a layer D comprising at least one metal oxide having a refractive index higher than or equal to 1.8 deposited on the layer B and in direct contact therewith.

26. The article of claim 25, wherein said layer D is not formed from organic precursor compounds.

27. The article of claim 25, wherein said layer D has been deposited under ion assistance.

28. The article of claim 16, wherein it possesses a layer C deposited on the layer A and in direct contact therewith, the layer C containing at least 50 wt % silica relative to the total weight of the layer C.

29. The article of claim 16, wherein it possesses a layer C having a thickness ranging from 2 to 10 nm deposited on the layer A and in direct contact therewith.

30. The article of claim 16, wherein the interference coating is an antireflection coating.

31. The article of claim 16, further defined as an optical lens.

32. The article of claim 16, further defined as an ophthalmic lens.

33. The article of claim 16, wherein said layer E is not formed from organic precursor compounds.

34. The article of claim 16, wherein said layer A contains more than 70% by weight of organosilicon compounds A with respect to the weight of the layer A.

35. A process for the manufacture of an article of claim 16, comprising at least the following steps:
supplying an article comprising a substrate having at least one main surface;
depositing, on said main surface of the substrate a layer A having a refractive index lower than or equal to 1.65;
depositing on said layer A:
either a layer B having a refractive index higher than 1.65 and containing at least one metal oxide having a refractive index higher than 1.8; or
a layer C comprising a silicon oxide and having a thickness lower than or equal to 15 nm, and depositing directly on said layer C a layer E comprising at least one metal oxide having a refractive index higher than or equal to 1.8;
collecting an article comprising a substrate having a main surface coated with an interference coating comprising, in order starting from the substrate, a layer A making direct contact with a layer B or a layer A making direct contact with a layer C making direct contact with a layer E;
said layer A having been obtained by vacuum deposition, assisted by a source of ions, of at least one organosilicon compound A, and said layer B, when it is present, having been obtained by vacuum deposition, assisted by a source of ions, and at least one metal oxide and at least one organosilicon compound B.
